(19) United States
(12) Patent Application Publication
(10) Pub. No.: US 2014/0299048 A1
(43) Pub. Date: Oct. 9, 2014

(54) METHOD OF MANUFACTURING SILICON CARBIDE SINGLE CRYSTAL

(71) Applicant: SUMITOMO ELECTRIC INDUSTRIES. LTD, Osaka-shi (JP)

(72) Inventors: Makoto SASAKI, Itami-shi (JP); Tsutomu HORI, Itami-shi (JP); Shunsaku UETA, Itami-shi (JP)

(73) Assignee: SUMITOMO ELECTRIC INDUSTRIES. LTD, Osaka-shi (JP)

(21) Appl. No.: 14/196,285

(22) Filed: Mar. 4, 2014

(30) Foreign Application Priority Data
Apr. 8, 2013 (JP) 2013-080324

(51) Int. Cl. C30B 23/00

(52) U.S. Cl. CPC C30B 23/002
USPC 117/84

(57) ABSTRACT

A temperature of a source material and a temperature of a seed substrate are defined as Tₘ and T_{S}, respectively. A silicon carbide single crystal is grown at a growth rate R≧R_{G} by heating the source material and the seed substrate so as to satisfy T_{S}<Tₘ and satisfy a temperature difference D≧D_{G}, where D represents an absolute value of a difference between Tₘ and Tₛ. R is decreased so as to satisfy R≦R_{R} in connection with R_{R} smaller than R_{G}. In decreasing R, the temperature difference D is decreased such that the temperature difference D≦D_{R} is satisfied in connection with D_{R} smaller than D_{G} while at least any of Tₘ and Tₛ is held at at least T_{R} not lower than 1800° C. The source material and the seed substrate are cooled such that each of Tₘ and Tₛ is lower than T_{R}.

### BACKGROUND OF THE INVENTION

1. Field of the Invention

The present invention relates to a method of manufacturing a silicon carbide single crystal, and particularly to a method of manufacturing a silicon carbide single crystal by using a sublimation recrystallization method.

2. Description of the Background Art

Silicon (Si) is most common as a semiconductor material, however, use of silicon carbide (SiC) has actively been studied in recent years. Wide band gap of SiC can contribute to enhancement of performance of a semiconductor device. In manufacturing an SiC semiconductor, normally, an SiC substrate is required. An SiC substrate (wafer) can be formed by slicing an SiC single crystal (ingot).

A sublimation recrystallization method is most common as a method suitable for mass production of SiC single crystals. In order to sufficiently sublime silicon carbide, a temperature exceeding 2000° C. is required. Therefore, in order to take the grown SiC single crystal out of a manufacturing apparatus therefor, initially, a temperature of the SiC single crystal should be cooled to around room temperature. The SiC single crystal or a substrate cut therefrom may break due to stress accumulated in the SiC single crystal during this cooling. Therefore, the SiC single crystal should appropriately be cooled. Japanese Patent Laying-Open No. 2007-290880 discloses setting a temperature difference between a central portion and an outer peripheral portion of an ingot to −50° C. or more and 5° C. or less during a process for cooling a silicon carbide single crystal.

According to the technique described in the publication above, a temperature gradient between the central portion and the outer peripheral portion of the ingot is suppressed. Namely, the temperature gradient in a radial direction of the ingot is suppressed. In spite of such consideration, however, according to the studies conducted by the present inventors, an ingot or a substrate cut from this ingot broke due to internal stress in some cases.

### SUMMARY OF THE INVENTION

An object of the present invention is to provide a method of manufacturing a silicon carbide single crystal in which internal stress is lowered.

A method of manufacturing a silicon carbide single crystal according to the present invention uses growth of silicon carbide on a seed substrate through recrystallization of a sublimate from a source material made of silicon carbide, and has the following steps.

The source material and the seed substrate are arranged at a distance from each other.

A silicon carbide single crystal is grown on the seed substrate at a growth rate R≧R_{G} by heating the source material and the seed substrate so as to satisfy a temperature Tₛ<Tₘ and satisfy a temperature difference D≧D_{G}, with a temperature of the source material being defined as a temperature Tₘ, a temperature of the seed substrate being defined as a temperature T_{S}, an absolute value of a difference between temperatures Tₘ and Tₛ being defined as a temperature difference D, a value D_{G} being defined as one value for temperature difference D, a growth rate of the silicon carbide single crystal being defined as R, and a value R_{G} being defined as one value for growth rate R.

Then, growth rate R is decreased so as to satisfy a growth rate R≦R_{R} in connection with a reference rate R_{R} smaller than R_{G}. In decreasing growth rate R, temperature difference D is decreased such that temperature difference D≦D_{R} is satisfied in connection with a reference temperature difference D_{R} smaller than D_{G} while at least any of temperature Tₘ and temperature Tₛ is held at at least a reference temperature T_{R} not lower than 1800° C.

Then, the source material and the seed substrate are cooled such that each of temperatures Tₘ and Tₛ is lower than reference temperature T_{R}.

According to this manufacturing method, temperature difference D is decreased such that temperature difference D≦D_{R} is satisfied while at least any of temperature Tₘ and temperature Tₛ is held at reference temperature T_{R} not lower than 1800° C. Thus, stress accumulated in a silicon carbide single crystal located between the source material and the seed substrate during cooling can be lessened.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a flowchart schematically showing a method of manufacturing a silicon carbide single crystal in one embodiment of the present invention.

FIG. 2 is a cross-sectional view schematically showing one step in the method of manufacturing a silicon carbide single crystal in one embodiment of the present invention.

FIG. 3 is a graph showing an example of change over time of a temperature difference D in one embodiment of the present invention.

FIG. 4 is a graph showing change over time of temperature difference D in a comparative example.

### DESCRIPTION OF THE PREFERRED EMBODIMENTS

An embodiment of the present invention will be described hereinafter with reference to the drawings.

(Outlines)

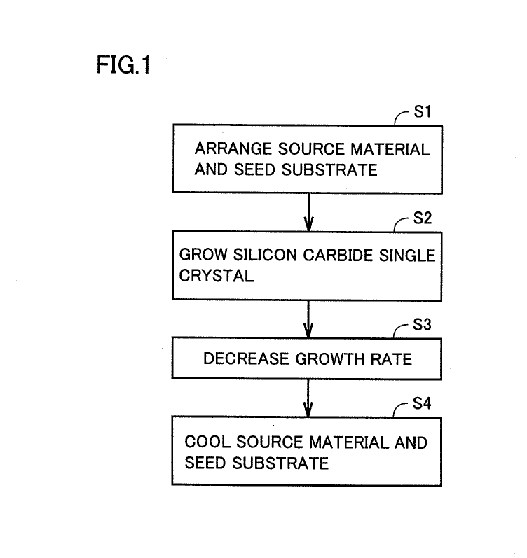

(i) A method of manufacturing a silicon carbide single crystal according to the present invention uses growth of silicon carbide on a seed substrate through recrystallization of a sublimate from a source material made of silicon carbide, and has the following steps S1 to S4 (FIG. 1).

A source material 11 and a seed substrate 12 are arranged at a distance from each other (step S1).

A temperature of source material 11 is defined as a temperature Tₘ, a temperature of seed substrate 12 is defined as a temperature T_{S}, an absolute value of a difference between temperatures Tₘ and T_{S} is defined as a temperature difference D, a value D_{G} is defined as one value for temperature difference D, a growth rate of a silicon carbide single crystal 19 is defined as R, and a value R_{G} is defined as one value for growth rate R. Silicon carbide single crystal 19 is grown on the seed substrate at a growth rate R≧R_{G} by heating source material 11 and seed substrate 12 so as to satisfy a temperature T_{S}<Tₘ and satisfy a temperature difference D≧D_{G} (step S2).

Then, growth rate R is decreased so as to satisfy a growth rate R≦R_{R} in connection with a reference rate R_{R} smaller than R_{G} (step S3). In decreasing growth rate R, temperature difference D is decreased such that temperature difference D≦D_{R} is satisfied in connection with a reference temperature difference D_{R} smaller than D_{G} while at least any of temperature Tₘ and temperature Tₛ is held at at least a reference temperature T_{R} not lower than 1800° C.

Then, the source material and the seed substrate are cooled such that each of temperatures Tₘ and Tₛ is lower than reference temperature T_{R} (step S4).

According to the present manufacturing method, temperature difference D is decreased such that temperature difference D≦D_{R} is satisfied while at least any of temperature Tₘ and temperature Tₛ is held at at least reference temperature T_{R} not lower than 1800° C. In other words, before cooling from around 1800° C. to room temperature is started, temperature difference D is decreased. Thus, in cooling, a temperature gradient in the silicon carbide single crystal located between the source material and the seed substrate is also lessened. Therefore, stress accumulated in a silicon carbide single crystal during cooling can be lessened.

(ii) In cooling the source material and the seed substrate in (i) above, transition from a state that at least any of temperature Tₘ and temperature Tₛ is not lower than reference temperature T_{R} to a state that each of temperature Tₘ and temperature Tₛ is at room temperature may be made.

Thus, a temperature of the silicon carbide single crystal can be set to room temperature while accumulation of stress is suppressed.

(iii) Transition in (ii) above may be made while temperature difference D≦D_{R} is maintained.

Thus, in a temperature region where stress is particularly likely to be accumulated in the silicon carbide single crystal in the cooling step, temperature difference D is kept small. Therefore, accumulated stress can more reliably be lessened.

(iv) In (i) to (iii) above, reference temperature T_{R} may be not lower than 2000° C.

Thus, in a wider temperature region in the cooling step, that is, not only in a temperature region not higher than 1800° C. but also in a temperature region not higher than 2000° C., temperature difference D can be kept small. Therefore, stress accumulated in the silicon carbide single crystal during cooling can further be lessened.

(v) In (i) to (iv) above, reference temperature difference D_{R} may be not greater than half of value D_{G}.

Thus, temperature difference D during cooling can further be kept smaller. Therefore, stress accumulated in the silicon carbide single crystal during cooling can further be lessened.

(vi) In (i) to (v) above, reference rate R_{R} may be not greater than half of value R_{G}.

Thus, at the time point when a rate of formation of a silicon carbide single crystal is further lowered, that is, at the time point when formation of a silicon carbide single crystal is more fully completed, adjustment for decreasing temperature difference D can be started. Therefore, influence on the step itself of forming a silicon carbide single crystal caused by providing the step of decreasing temperature difference D can further be lessened.

(vii) In (i) to (vi) above, in decreasing temperature difference D, a relative position between each of the source material and the seed substrate and a heating portion for heating the source material and the seed substrate may be changed.

Thus, adjustment for decreasing temperature difference D can be made by adjusting the relative position above.

(Details)

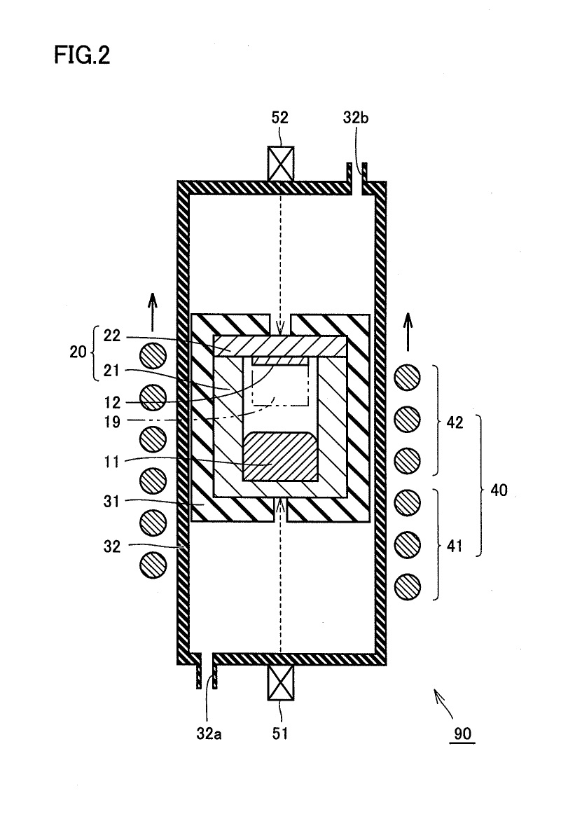

A manufacturing apparatus 90 used for a method of manufacturing an ingot 19 (a silicon carbide single crystal) in the present embodiment will be described with reference to FIG. 2.

Manufacturing apparatus 90 is an apparatus for growing ingot 19 of silicon carbide with a sublimation recrystallization method. Namely, manufacturing apparatus 90 uses growth of silicon carbide on seed substrate 12 through recrystallization of a sublimate from source material 11 made of silicon carbide. This growth can be achieved by holding a temperature of seed substrate 12 at a temperature slightly lower than a temperature of the source material while the temperature of source material 11 is set at least to a temperature at which silicon carbide can sublime. A temperature gradient between source material 11 and seed substrate 12 formed by this temperature difference is necessary for causing sublimation recrystallization.

Manufacturing apparatus 90 has a crucible 20, a heat insulating material 31, a container 32, a heating portion 40, and radiation thermometers 51 and 52.

Crucible 20 has a main body portion 21 and a lid portion 22. Main body portion 21 has a space for accommodating source material 11 for the sublimation recrystallization method therein. Lid portion 22 can be attached to main body portion 21 so as to close this space. In addition, lid portion 22 holds seed substrate 12 such that it is opposed to source material 11 in this space. Crucible 20 is made, for example, of graphite.

Container 32 contains crucible 20. Container 32 has a gas introduction port 32a and a gas exhaust port 32b for controlling an atmosphere and a pressure therein.

Radiation thermometers 51 and 52 serve for measuring a temperature of a specific portion within container 32. Radiation thermometer 51 is arranged to be able to measure a temperature of main body portion 21 of crucible 20. Radiation thermometer 52 is arranged to be able to measure a temperature of lid portion 22 of crucible 20. By measuring a temperature of main body portion 21, a temperature of source material 11 accommodated in main body portion 21 can be known. In addition, by measuring a temperature of lid portion 22, a temperature of seed substrate 12 attached to lid portion 22 can be known.

Heat insulating material 31 covers a part of an outer surface of crucible 20. Heat insulating material 31 preferably has an opening exposing each of main body portion 21 of crucible 20 and lid portion 22 of crucible 20 so as not to impede measurement by radiation thermometers 51 and 52. Heat insulating material 31 is made, for example, of carbon felt.

Heating portion 40 is provided outside crucible 20. Heating portion 40 serves to heat source material 11 and seed substrate 12. Heating portion 40 is implemented, for example, by a high-frequency heating coil or a resistance heater. It is noted that the high-frequency heating coil is preferably arranged outside heat insulating material 31. The resistance heater is preferably arranged inside heat insulating material 31.

Heating portion 40 is configured to be able to adjust each of a temperature of source material 11 and a temperature of seed substrate 12. For this purpose, heating portion 40 may be configured to be able to displace in a direction in which source material 11 and seed substrate 12 are opposed to each other (a direction shown with an arrow in the figure). In addition, heating portion 40 may have a lower portion 41 and an upper portion 42 of which power can be controlled independently of each other. Of these portions, lower portion 41 is arranged closer to source material 11 and the upper portion is arranged closer to seed substrate 12.

A method of manufacturing ingot 19 with the use of manufacturing apparatus 90 will now be described.

Referring to FIG. 2, source material 11 made of silicon carbide is accommodated in main body portion 21. Source material 11 is, for example, polycrystalline powders or a sintered object.

Seed substrate 12 is attached to lid portion 22. Seed substrate 12 is a single crystal made of silicon carbide. Crystal structure of silicon carbide of seed substrate 12 is preferably hexagonal. In addition, a poly type of the crystal structure is preferably 4H or 6H. Then, lid portion 22 is attached to main body portion 21. Thus, source material 11 and seed substrate 12 are arranged at a distance from each other (FIG. 1: step S1).

A temperature of source material 11 is defined as temperature Tₘ. Temperature Tₘ can be known by using radiation thermometer 51. A temperature of seed substrate 12 is defined as temperature T_{S}. Temperature T_{S} can be known by using radiation thermometer 52. An absolute value of a difference between temperatures Tₘ and Tₛ is defined as temperature difference D. Value D_{G} is defined as one value for temperature difference D. A growth rate of ingot 19 is defined as R. Value R_{G} is defined as one value for growth rate R. Values D_{G} and R_{G} are prescribed values determined in view of at which rate ingot 19 is to be grown.

By heating source material 11 and seed substrate 12 such that temperature T_{S}<Tₘ is satisfied and temperature difference D≧D_{G} is satisfied, ingot 19 is grown on seed substrate 12 at growth rate R≧R_{G} (FIG. 1: step S2). Specifically, the following steps are performed.

Heating portion 40 heats source material 11 to a temperature at which source material 11 sublimes. Thus, as source material 11 sublimes, a sublimation gas (a source material gas) is generated. This sublimation gas is recrystallized on seed substrate 12 set to a temperature lower than a temperature of source material 11. For example, temperature Tₘ of source material 11 is held at a temperature not lower than 2100° C. and not higher than 2450° C., and temperature Tₛ of seed substrate 12 is held at a temperature not lower than 2000° C. and not higher than 2250° C.

After ingot 19 grows to a desired thickness, the step of substantially stopping growth of ingot 19 is started. Namely, growth rate R is decreased so as to satisfy R≦R_{R} in connection with reference rate R_{R} smaller than R_{G} (FIG. 1: step S3). Reference rate R_{R} is preferably not greater than half of value R_{G} described above. Reference rate R_{R} is, for example, around 0.1 mm/h. Growth rate R can be decreased by increasing a pressure in container 32. In addition, growth rate R can be decreased also by lowering temperature Tₘ to around 2000° C. Moreover, growth rate R can be decreased also by decreasing temperature difference D as will be described later.

In decreasing growth rate R, temperature difference D is made smaller such that temperature difference D≦D_{R} is satisfied in connection with reference temperature difference D_{R} smaller than D_{G} while at least any of temperature Tₘ and temperature Tₛ is held at reference temperature T_{R} or higher. Reference temperature difference D_{R} is preferably not greater than half of value D_{G}, and it is more preferably not greater than ¼ of value D_{G}. Reference temperature difference D_{R} is, for example, around 10° C.

Reference temperature T_{R} is an indicator of a temperature at which accumulation of stress in ingot 19 is noticeable, and at a temperature higher than that, plastic deformation in ingot 19 is likely and hence accumulation of stress is regarded as less. Therefore, as a process condition is set with reference temperature T_{R} being estimated higher, accumulation of compressive stress can further be suppressed. For this purpose, reference temperature T_{R} should be not lower than 1800° C. and it is preferably not lower than 2000° C.

In decreasing temperature difference D, a relative position between each of source material 11 and seed substrate 12 and heating portion 40 for heating source material 11 and seed substrate 12 may be changed. Specifically, of heating of source material 11 and heating of seed substrate 12 by heating portion 40, the latter is desirably relatively more dominant. Such a step can be performed by displacing heating portion 40, for example, in a direction from source material 11 toward seed substrate 12 as shown with the arrow in FIG. 2. Alternatively, of power of lower portion 41 and power of upper portion 42, the latter is desirably relatively higher.

Then, source material 11 and seed substrate 12 are cooled such that each of temperatures Tₘ and Tₛ is lower than reference temperature T_{R} (FIG. 1: step S4). In cooling of source material 11 and seed substrate 12, transition from a state that at least any of temperature Tₘ and temperature Tₛ is not lower than reference temperature T_{R} to a state that each of temperature Tₘ and temperature Tₛ is at room temperature is preferably made. This transition is preferably made while temperature difference D≦D_{R} is maintained.

Ingot 19 is obtained as above. As necessary, seed substrate 12 may be removed.

Then, change over time of temperature difference D described above will be discussed below.

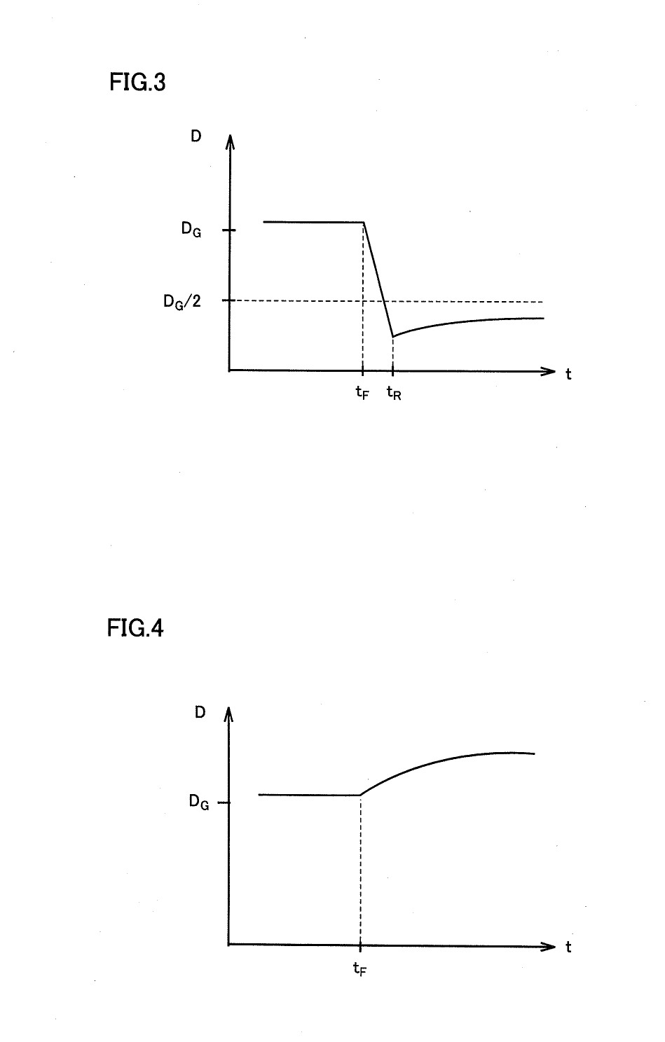

In the present embodiment, referring to FIG. 3, initially, during a period until time t_{F}, temperature difference D≧D_{G} is satisfied, so that ingot 19 is grown at sufficient growth rate R (FIG. 1: step S2). During a period from time t_{F} to t_{R}, growth is substantially stopped (FIG. 1: step S3). Here, as described above, temperature difference D is equal to or smaller than reference temperature difference D_{R} smaller than D_{G} and preferably equal to or smaller than half of D_{G}.

Then, at time t_{R} and later, substantial cooling is performed (FIG. 1: step S4). As shown in the graph in FIG. 3, immediately after substantial cooling is started, that is, immediately after time t_{R}, temperature difference D tends to increase, because immediately after heating by heating portion 40 is significantly weakened or stopped for the purpose of cooling, temperature Tₘ , of source material 11 is less likely to lower due to a large thermal capacity of source material 11, while temperature T_{S} of seed substrate 12 is more likely to lower. By making temperature difference D sufficiently small by time t_{F}, temperature difference D can be equal to or smaller than desired reference temperature difference D_{R} even though temperature difference D increases to some extent after time t_{F}. In addition, even after time t_{F}, heating portion 40 may be controlled so as to decrease temperature difference D. Thus, a state that temperature difference D is small can more reliably be maintained. Preferably, a state that temperature difference D is thus not greater than temperature difference D_{R} is kept until a temperature of each of source material 11 and seed substrate 12 is set to room temperature.

In a comparative example, that is, in a case that the step for decreasing temperature difference D is not performed, referring to FIG. 4, immediately after cooling is started, that is, immediately after time t_{F}, as described above, temperature difference D tends to increase because of a large thermal capacity of source material 11. As cooling proceeds while temperature difference D is thus great, large stress is accumulated in ingot 19.

According to the present embodiment, temperature difference D is decreased such that temperature difference D≦D_{R} is satisfied while at least any of temperature Tₘ and temperature Tₛ is held at at least reference temperature T_{R} not lower than 1800° C. In other words, before cooling from around 1800° C. to room temperature is started, temperature difference D is decreased. Thus, in cooling, a temperature gradient within ingot 19 located between source material 11 and seed substrate 12 is also lessened. Therefore, stress accumulated in ingot 19 during cooling can be lessened.

In cooling source material 11 and seed substrate 12, transition from a state that at least any of temperature Tₘ and temperature Tₛ is not lower than reference temperature T_{R} to a state that each of temperature Tₘ and temperature Tₛ is at room temperature is preferably made. Thus, a temperature of ingot 19 can be set to room temperature while accumulation of stress is suppressed. This transition is preferably made while temperature difference D≦D_{R} is maintained. Thus, in a temperature region where stress is particularly likely to be accumulated in ingot 19 in the cooling step, temperature difference D is kept small. Therefore, accumulated stress can more reliably be lessened.

Preferably, reference temperature T_{R} is not lower than 2000° C. Thus, in a wider temperature region in the cooling step, that is, not only in a temperature region not higher than 1800° C. but also in a temperature region not higher than 2000° C., temperature difference D can be kept small. Therefore, stress accumulated in ingot 19 during cooling can further be lessened.

Preferably, reference temperature difference D_{R} is not greater than half of value D_{G}. Thus, temperature difference D during cooling can further be kept smaller. Therefore, stress accumulated in ingot 19 during cooling can further be lessened.

Preferably, reference rate R_{R} is not greater than half of value R_{G}. Thus, at the time point when a rate of formation of ingot 19 is further lowered, that is, at the time point when formation of ingot 19 is more fully completed, adjustment for decreasing temperature difference D can be started. Therefore, influence on the step itself of forming ingot 19 caused by providing the step of decreasing temperature difference D can further be lessened.

In decreasing temperature difference D, a relative position between each of source material 11 and seed substrate 12 and heating portion 40 for heating source material 11 and seed substrate 12 may be changed. Thus, adjustment for decreasing temperature difference D can be made by adjusting the relative position above.

(Additional Description)

Characteristics of ingots obtained in an example of the present embodiment and ingots in a comparative example will be described below.

In each of the example and the comparative example, ten ingots 19 each having a diameter of 100 mm were manufactured. A plurality of wafers were obtained from each ingot 19 by cutting with a wire saw. Among these wafers, warpage of wafers located at a distance from seed substrate 12 within ⅕ of a height of ingot 19 was defined as A, warpage of wafers located at a distance from an uppermost surface of ingot 19 within ⅕ of the height of ingot 19 was defined as B, and a ratio AB was determined. For each ingot in the example, relation of 100%≧A/B≧80% was satisfied. On the other hand, in each ingot in the comparative example, relation was 80%>A/B. This result is considered to correspond to the fact that stress accumulation in ingot 19 was less in the example than in the comparative example.

In addition, stress distribution in wafers cut from each ingot above was determined based on photoelasticity measurement for polished wafers. Consequently, stress of each wafer in the example was lower than 150 MPa at all measurement positions. In contrast, wafers in the comparative example locally had a portion where stress was not lower than 150 MPa. This result is considered to correspond to the fact that stress accumulation in ingot 19 was less in the example than in the comparative example.

Ingots each having a diameter of 150 mm were also subjected to warpage measurement and stress distribution determination described above. Results were substantially the same as described above.

Although the present invention has been described and illustrated in detail, it is clearly understood that the same is by way of illustration and example only and is not to be taken by way of limitation, the scope of the present invention being interpreted by the terms of the appended claims.

What is claimed is:

1. A method of manufacturing a silicon carbide single crystal by using growth of silicon carbide on a seed substrate through recrystallization of a sublimate from a source material made of silicon carbide, comprising the steps of:
arranging said source material and said seed substrate at a distance from each other;
growing a silicon carbide single crystal on said seed substrate at a growth rate R≧R_{G} by heating said source material and said seed substrate so as to satisfy a temperature Tₛ<Tₘ and satisfy a temperature difference D≧D_{G}, with a temperature of said source material being defined as a temperature Tₘ, a temperature of said seed substrate being defined as a temperature T_{S}, an absolute value of a difference between the temperatures ₘ and Tₛ being defined as a temperature difference D, a value D_{G} being defined as one value for temperature difference D, a growth rate of said silicon carbide single crystal being defined as R, and a value R_{G} being defined as one value for growth rate R;
decreasing growth rate R so as to satisfy a growth rate R≦R_{R} in connection with a reference rate R_{R} smaller than R_{G} after said growing step, the step of decreasing growth rate R including the step of decreasing temperature difference D such that temperature difference D≦D_{R} is satisfied in connection with a reference temperature difference D_{R} smaller than D_{G} while at least any of temperature Tₘ and temperature Tₛ is held at at least a reference temperature T_{R} not lower than 1800° C.; and
cooling said source material and said seed substrate such that each of temperatures Tₘ and Tₛ is lower than reference temperature T_{R} after the step of decreasing temperature difference D.

2. The method of manufacturing a silicon carbide single crystal according to claim 1, wherein
said cooling step includes the step of making transition from a state that at least any of temperature Tₘ and temperature Tₛ is not lower than reference temperature T_{R} to a state that each of temperature Tₘ and temperature Tₛ is at room temperature.

3. The method of manufacturing a silicon carbide single crystal according to claim 2, wherein
said step of making transition is performed while temperature difference D≦D_{R} is maintained.

4. The method of manufacturing a silicon carbide single crystal according to claim 1, wherein
reference temperature T_{R} is not lower than 2000° C.

5. The method of manufacturing a silicon carbide single crystal according to claim 1, wherein
reference temperature difference D_{R} is not greater than half of value D_{G}.

6. The method of manufacturing a silicon carbide single crystal according to claim 1, wherein
reference rate R_{R} is not greater than half of value R_{G}.

7. The method of manufacturing a silicon carbide single crystal according to claim 1, wherein
said step of decreasing temperature difference D includes the step of changing a relative position between each of said source material and said seed substrate and a heating portion for heating said source material and said seed substrate.
